(19) United States
(12) Patent Application Publication
(10) Pub. No.: US 2006/0270241 A1
(43) Pub. Date: Nov. 30, 2006

(54) METHOD OF REMOVING A PHOTORESIST PATTERN AND METHOD OF MANUFACTURING A SEMICONDUCTOR DEVICE USING THE SAME

(76) Inventors: Kyoung-Chul Kim, Suwon-si (KR); Dae-Keun Kang, Gunpo-si (KR); Se-Ho Cha, Goyang-si (KR); In-Seak Hwang, Suwon-si (KR); Keum-Joo Lee, Hwaseong-si (KR)

Correspondence Address: HARNESS, DICKEY & PIERCE, P.L.C., P.O. BOX 8910, RESTON, VA, 20195, US

(21) Appl. No.: 11/420,943

(22) Filed: May 30, 2006

(30) Foreign Application Priority Data
May 30, 2005 (KR) 2005-45385

(51) Int. Cl. B08B 3/00; C23G 1/00; H01L 21/302

(52) U.S. Cl. 438/725; 134/26; 134/2

(57) ABSTRACT

In a method of removing a photoresist pattern from a substrate without deteriorating a lower electrode or increasing processing time, ozone gas may be provided onto a substrate on which a photoresist pattern may be formed. An oxidation-decomposition process may be carried out using the ozone gas, to thereby decompose the photoresist pattern on the substrate. The decomposed photoresist pattern may be dissolved into water and removed from the substrate in a rinsing process. Accordingly, a photoresist pattern in an opening having a relatively high aspect ratio may be sufficiently removed from a substrate without deteriorating the lower electrode or increasing processing time.

### PRIORITY STATEMENT

This application claims priority under 35 U.S.C. § 119 to Korean Patent Application No. 2005-45385 filed on May 30, 2005, in the Korean Intellectual Property Office (KIPO), the entire contents of which are herein incorporated by reference.

### BACKGROUND

1. Field

Example embodiments of the present invention relate to a method of removing a photoresist pattern, for example, a method of removing a photoresist pattern remaining in an opening, and a method of manufacturing a semiconductor device using the same, for example, a method of manufacturing a semiconductor device having a lower electrode using the same.

2. Description of the Related Art

Recently, an integration degree of a dynamic random access memory (DRAM) device has increased up to a gigabyte scale so that the allowable space per a cell of the DRAM device has continuously decreased. Accordingly, a conventionally flat-shaped capacitor now may have various structures such as a tube structure or a cylindrical structure to ensure a desired capacitance of the capacitor. However, as for the DRAM device having a critical dimension below about 0.11 μm, the cell of the DRAM device also may have an extremely reduced area so that the capacitor inevitably has a relatively high aspect ratio to meet the desired capacitance.

The capacitor may have a stacked structure including a cylindrical lower electrode, a dielectric layer and an upper electrode. A conductive layer may be continuously formed on a mold layer pattern having an opening. The conductive layer may be node-separated by a chemical mechanical polishing (CMP) process or an etch-back process. The mold layer pattern may be removed using a cleaning solution including hydrogen fluoride. As a result, a formation of the lower electrode of the capacitor may be completed on a substrate.

In a removing process of the mold layer pattern, the lower electrode may be etched by the cleaning solution so that the cleaning solution penetrates into boundaries of grains of the lower electrode. Thus, a pad, which is electrically connected to the lower electrode, may be deteriorated. A sacrificial layer may be formed to plug the opening before the conductive layer is node-separated in order to retard deterioration. The sacrificial layer may include a photoresist film. When the mold layer pattern is removed by the cleaning solution, the sacrificial layer including the photoresist film may retard, or prevent, etching of the lower electrode by the cleaning solution or retard, or prevent penetration into the lower electrode. However, the photoresist film may not be easily removed by a conventional process. In particular, the photoresist film remains on a cylindrical lower electrode that may be formed on a sidewall of an opening. The remaining photoresist film in the opening may not be easily removed by a conventional ashing process so that the remaining photoresist film may work as a resistor to cause an operation failure of a capacitor in a semiconductor device.

In order to increase efficiency of removing the sacrificial layer in the opening, an oxygen plasma ashing process may be carried out at a relatively high temperature of about 150° C. to about 250° C. However, the lower electrode may be damaged or oxidated by the ashing process because of the relatively high temperature so that the capacitor, including the lower electrode, may have insufficient capacitance.

When the ashing process is performed at a temperature of about 250° C. for a relatively long time, the lower electrode may be damaged.

The conventional art discloses a method of cleaning a substrate. In the conventional art, a cleaning gas including ozone gas and/or a pure water vapor may be introduced into a chamber. The cleaning gas may remove contaminants from the substrate. The chamber may be purged and the substrate may be rinsed. A concentration of the ozone gas may range from about 10 ppm to about 100,000 ppm.

However, the above method may not be appropriately employed in removing a photoresist film that has a relatively large thickness and remains in an opening, even though the above method may be employed in removing organic compounds that remain on the substrate. Further, because the cleaning gas includes other substances other than the ozone gas, the sacrificial layer containing a photoresist for forming the lower electrode may not be completely removed from the substrate.

### SUMMARY

Example embodiments of the present invention may provide a method of removing a photoresist pattern in an opening of a relatively high aspect ratio using ozone gas.

Example embodiments of the present invention may provide a method of manufacturing a semiconductor device including a capacitor in which a sacrificial layer such as a photoresist pattern may be removed from a substrate using ozone gas without any damage to a lower electrode.

According to one example embodiment of the present invention, there may be provided a method of removing a photoresist pattern from a substrate. In the method of removing the photoresist pattern, ozone gas may be provided onto a substrate on which the photoresist pattern may be formed. A decomposition process may be performed on the substrate through an oxidation reaction using the ozone gas to remove the photoresist pattern from the substrate. In an example embodiment of the present invention, the ozone gas may have a gas density of about 250 g/cm³.150 g/m³ to about 250 g/m³.

According to another example embodiment of the present invention, there may be provided a method of removing a photoresist pattern remaining in an opening having a relatively high aspect ratio from a substrate. Ozone gas may be provided onto the substrate on which the opening may be formed including the photoresist pattern. A decomposition process may be performed in the opening through an oxidation reaction using the ozone gas to thereby remove the photoresist pattern from the substrate in the opening.

In an example embodiment of the present invention, an ashing process may be further performed on the substrate using plasma so that the photoresist pattern may be partially removed from the substrate.

In an example embodiment of the present invention, a rinsing process may be further performed on the substrate using water so that the decomposed photoresist pattern due to the oxidation-decomposition process may be dissolved into the water.

In an example embodiment of the present invention, the oxidation-decomposition process may be carried out at a temperature of about 80° C. to about 120° C.

In an example embodiment of the present invention, the oxidation-decomposition process may be carried out under a pressure of about 40 kpa to about 100 kpa.

In an example embodiment of the present invention, the substrate may include an opening in which the photoresist pattern may be formed. For example, the opening may have an aspect ratio of about 1:9 to about 1:40.

In an example embodiment of the present invention, a conductive pattern may be continuously formed on a sidewall and/or a bottom of the opening.

According to an example embodiment of the present invention, the photoresist pattern in the opening may be removed from the substrate without deterioration of a conductive pattern in a short time, thereby reducing processing defects during the manufacturing process of a semiconductor device.

According to an example embodiment of the present invention, there may be provided a method of manufacturing a semiconductor device. In the method of manufacturing the semiconductor device, a mold layer having an opening may be formed on a substrate. A lower electrode layer may be continuously formed on a sidewall and/or a bottom of the opening and/or on the mold layer. A photoresist film may be formed on the mold layer to a thickness sufficient to plug the opening. The lower electrode layer and/or the photoresist film may be planarized by a planarization process until a top surface of the mold layer is exposed so that the lower electrode layer and/or the photoresist film only remain in the opening, thereby to form a lower electrode and/or a photoresist pattern on the substrate. The photoresist pattern may be decomposed through an oxidation reaction using ozone gas provided onto the substrate. The decomposed photoresist pattern may be removed from the substrate.

In an example embodiment of the present invention, the photoresist pattern may be partially removed from the substrate by an ashing process using oxygen plasma.

In an example embodiment of the present invention, the ozone gas may have a gas density of about 150 g/m³ to about 250 g/m³.

In an example embodiment of the present invention, the photoresist pattern may be decomposed at a temperature of about 80° C. to about 120° C.

In an example embodiment of the present invention, the photoresist pattern may be decomposed under a pressure of about 40 kpa to about 100 kpa.

In an example embodiment of the present invention, the mold layer may be further removed from the substrate to thereby expose the lower electrode.

In an example embodiment of the present invention, an aspect ratio of the opening may range from about 1:9 to about 1:40.

According to an example embodiment of the present invention, no residual photoresist pattern may remain on the lower electrode to thereby reduce electrical resistance of a capacitor due to the residual photoresist pattern and improve capacitance of the capacitor, including the lower electrode. The photoresist pattern in the opening may be sufficiently removed without increasing a process time or a process temperature to thereby improve a throughput of the semiconductor device.

### BRIEF DESCRIPTION OF THE DRAWINGS

The above and other features and advantages of example embodiments of the present invention will become more apparent by describing in detailed example embodiments thereof with reference to the accompanying drawings, in which:

FIG. 1 is a flow chart illustrating a method of removing a photoresist film in accordance with an example embodiment of the present invention;

FIG. 2 is a flow chart illustrating a method of removing a photoresist in accordance with an example embodiment of the present invention;

FIGS. 3 to 10 illustrate processing steps for a method of manufacturing a semiconductor device in accordance with an example embodiment of the present invention; and

FIG. 11 is a graph showing a removal amount of the photoresist film in relation to a reaction time of the oxidation-decomposition reaction.

### DETAILED DESCRIPTION OF THE EXAMPLE EMBODIMENTS OF THE PRESENT INVENTION

Various example embodiments of the present invention will now be described more fully with reference to the accompanying drawings, in which some example embodiments of the present invention are shown. Example embodiments of the present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of the example embodiments of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments of the present invention.

Unless otherwise defined, all terms (including technical and scientific terms) used herein have the same meaning as commonly understood by one of ordinary skill in the art to which this present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

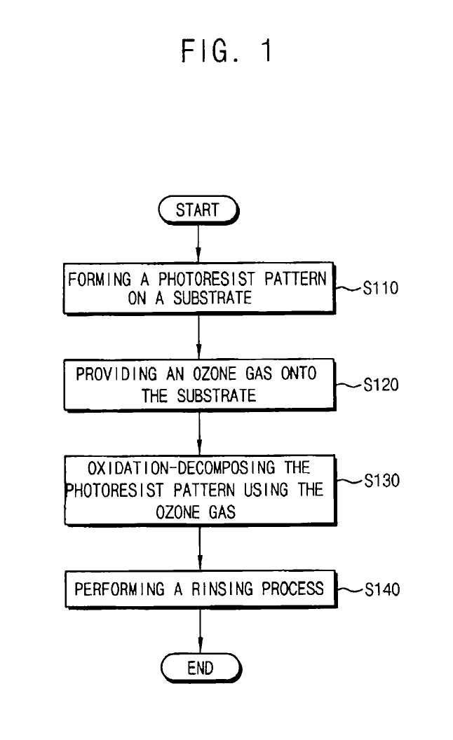

FIG. 1 is a flow chart illustrating a method of removing a photoresist film in accordance with an example embodiment of the present invention.

Referring to FIG. 1, a photoresist pattern may be formed on a substrate at S110.

For example, the photoresist pattern may include a mask pattern to apply an etching process. For example, contaminants on a surface of the substrate may be removed by a cleaning process, and a photoresist film may be coated on the substrate through a deposition process such as a CVD process. A first baking process may be performed on the photoresist film to thereby improve an adhesive strength of the photoresist film with respect to the substrate. The photoresist film may be selectively exposed to a light through an exposure process. In the exposure process, a laser having various wavelengths may be used as the light. For example, a laser having a wavelength of about 248 nm (laser of krypton fluorine) or a laser having a wavelength of about 193 nm (laser of argon fluorine) may be used as the light for the exposure process. A second baking process may be carried out on the selectively exposed photoresist film and a developing process may be performed on the photoresist film so that the photoresist film may be partially melted off from the substrate by a developing solution. A rinsing process may be carried out on the developed photoresist film and residuals on the photoresist film, thereby forming a photoresist pattern on the substrate.

The photoresist pattern may include a residual photoresist film remaining on a sidewall of an opening formed on/over the substrate. The photoresist pattern may also include a sacrificial layer in a node separation process to form a lower electrode of a capacitor. When the photoresist pattern corresponds to the sacrificial layer in the node separation process, the photoresist pattern may plug an opening on which the lower electrode may be formed.

The opening may have an aspect ratio of about 1:9 to about 1:40, for example, an aspect ratio of about 1:15 to about 1:30. The photoresist pattern that plugs the opening having the above aspect ratio may be completely removed by a succeeding process. However, the photoresist pattern in the opening may be difficult to remove by an oxygen plasma ashing process or an ozone plasma ashing process.

At S120, ozone gas for removing the photoresist pattern may be provided onto the substrate having the photoresist pattern.

When the ozone gas has a gas density less than about 150 g/m³, an amount of the ozone gas may be so small that there is little chance of chemical reaction between ozone and polymer in the photoresist pattern, and the polymer in the photoresist pattern may be decomposed through an oxidation reaction. The low density of the ozone gas may also require a long time to resolve the polymer in the photoresist pattern. In contrast, when the ozone gas has a gas density of more than about 250 g/m³, ozone may be sufficiently reacted with polymer in the photoresist pattern so that the polymer in the photoresist pattern may be sufficiently decomposed by an oxidation reaction. However, to increase the gas density of the ozone gas above about 250 g/m³ may be difficult.

Accordingly, the ozone gas may have a gas density ranging from about 150 g/m³ to about 250 g/m³. The ozone gas may be generated by an ozone generator using an oxygen gas as a source gas. The ozone gas may include a pure ozone gas (O₃) and/or an oxygen gas (O₂).

At S130, the photoresist pattern may be decomposed by an oxidation reaction using the ozone gas having the above gas density.

For example, the photoresist pattern may be decomposed by an oxidation reaction using the ozone gas at a temperature of about 80° C. to about 120° C. under a pressure of about 40 kPa to about 100 kPa. The decomposition generated by an oxidation reaction may be referred to as an oxidation-decomposition reaction/process.

When the oxidation-decomposition process is carried out at a temperature below about 80° C., reaction velocity of the oxidation-decomposition may be negligible, which would reduce efficiency of the removal of the photoresist pattern. When the oxidation-decomposition process is carried out at a temperature above about 120° C., the reaction temperature may be high enough that ozone (O₃) for the oxidation reaction is decomposed into elements and a conductive layer pattern on the substrate may be deteriorated.

The oxidation-decomposition of the photoresist pattern may be initiated by a chemical reaction between ozone (O₃) and carbon (C) in the polymer of the photoresist pattern. In particular, ozone (O₃) and/or oxygen (O₂) in the ozone gas may be reacted with carbon (C) in the polymer of the photoresist pattern to generate carbon dioxide (CO₂) or carbon oxide (CO). As a result, the photoresist pattern may be decomposed by an oxidation reaction. The decomposed photoresist pattern may be dissolved into water.

At S140, the decomposed photoresist pattern may be cleared off from the substrate by a rinsing process so that the photoresist pattern may be removed from the substrate.

The rinsing process may include a cleaning process to clear the decomposed photoresist pattern from the substrate using water due to relatively high solubility of the decomposed photoresist pattern with respect to the water. In one example embodiment of the present invention, the rinsing process may be performed by dipping the substrate into a container that includes deionized water and/or the like and by applying an ultrasonic wave to the substrate. In another example embodiment of the present invention, the rinsing process may be carried out by injecting the deionized water and/or the like into a rotating substrate.

According to some example embodiments of the present invention, the photoresist pattern may be removed from the substrate without any damage to the substrate and any deterioration to a thin layer on the substrate. The complete removal of the photoresist pattern from the substrate may require no additional process time, to thereby improve a throughput of a semiconductor device.

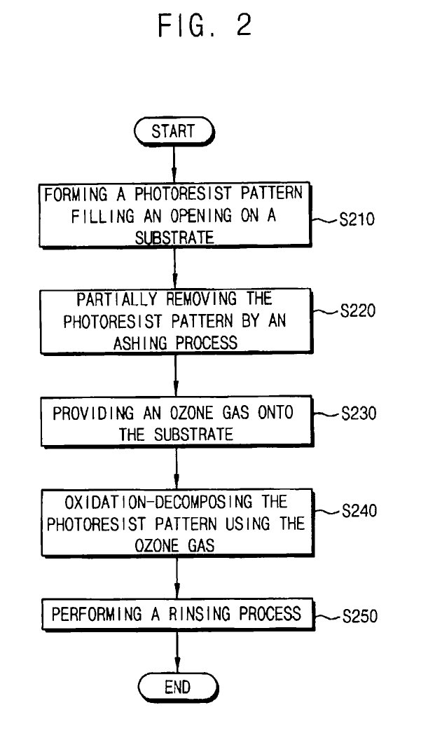

FIG. 2 is a flow chart illustrating a method of removing a photoresist in accordance with an example embodiment of the present invention.

Referring to FIG. 2, a photoresist pattern may be formed on a substrate and an opening may be filled with the photoresist pattern at S210.

The photoresist pattern may correspond to a residual photoresist film remaining in an opening of the substrate. The photoresist pattern may also correspond to a sacrificial layer in an opening that may be formed through a mold layer pattern and may include a conductive layer along an inner sidewall. The sacrificial layer may be used in a node separation process for forming the conductive layer into a lower electrode. In an example embodiment of the present invention, the photoresist pattern may include the sacrificial layer plugging an opening having a cylindrical lower electrode formed along an inner sidewall.

The opening may have an aspect ratio of about 1:9 to about 1:40. For example, the opening may have an aspect ratio of about 1:15 to about 1:30. A residual photoresist layer remaining in the opening may need to be completely removed in a following process.

The photoresist pattern in the opening may be partially removed from the substrate by an ashing process using oxygen plasma at S220.

An oxygen gas and an inactive gas may be introduced into a plasma reactor and excited into plasma, and the photoresist pattern in the opening may be partially decomposed by an oxidation reaction using the oxygen plasma. A rinsing process may be further performed on the substrate so as to clear off the byproducts of the oxidation-decomposition reaction from the substrate.

A photoresist pattern used as an etching mask may be sufficiently removed from the substrate by the ashing process using the oxygen plasma. However, a photoresist pattern plugging an opening having a relatively high aspect ratio no less than about 1:10 may not be sufficiently removed by the ashing process using the oxygen plasma because of a non-directed characteristic of the oxygen plasma. The oxygen plasma may be diffused at the same rate in all directions so that the oxygen plasma may not reach a bottom portion of the opening of a relatively high aspect ratio. Thus, the photoresist pattern in the opening of a relatively high aspect ratio may not be completely removed from the substrate. The photoresist pattern in the opening may be partially decomposed in the ashing process using the oxygen plasma.

At S230, ozone gas may be provided onto the substrate on which the photoresist pattern still remains in the opening despite the ashing process for partially removing the photoresist pattern at S220.

The ozone gas may have a gas density of about 150 g/m³ to about 250 g/m³. The ozone gas in an example embodiment of the present invention may be substantially the same as the one described with reference to FIG. 1.

At S240, the residual photoresist pattern in the opening may be decomposed by an oxidation reaction using the ozone gas having the above gas density.

For example, the photoresist pattern remaining on the substrate may be decomposed by an oxidation reaction using the ozone gas at a temperature of about 80° C. to about 120° C. under a pressure of about 40 kpa to about 100 kpa.

The oxidation-decomposition process for the photoresist pattern may be initiated by a chemical reaction between ozone (O₃) and carbon (C) in the polymer of the photoresist pattern. Because the decomposed photoresist pattern may have a characteristic of relatively high solubility with respect to water, a subsequent rinsing process may easily remove the photoresist pattern from the substrate.

At S250, a rinsing process may be performed on the substrate including the decomposed photoresist pattern using deionized water, and the decomposed photoresist pattern may be removed from the substrate. As a result, most of the photoresist pattern filling the opening of a relatively high aspect ratio may be removed from the substrate and may not remain on the substrate.

The process conditions disclosed in an example embodiment of the present invention may be efficient for manufacturing a semiconductor device.

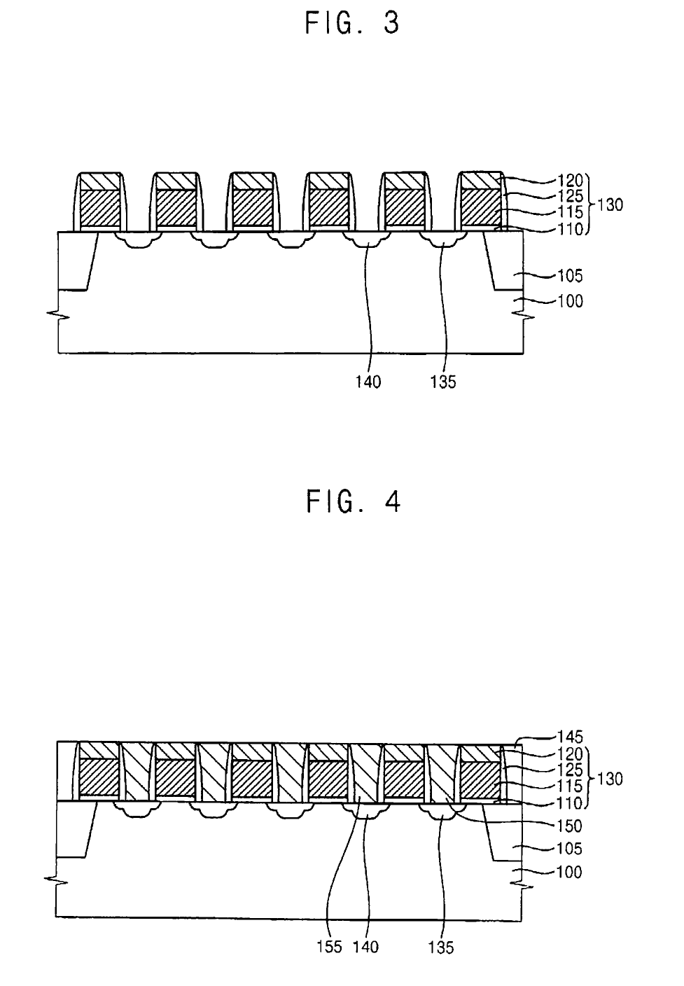

FIGS. 3 to 10 illustrate processing steps for a method of manufacturing a semiconductor device in accordance with an example embodiment of the present invention.

FIG. 3 illustrates processing for forming a gate structure and a contact region on a semiconductor substrate.

Referring to FIG. 3, an insulation layer 105 electrically isolating conductive structures from each other (hereinafter, referred to as a device isolation layer) may be formed on a semiconductor substrate 100. A device isolation layer 105 may be formed in a field region of a substrate 100 by a device isolation process such as a shallow trench isolation (STI) process, a thermal oxidation process and a local oxidation of silicon (LOCOS). An active region of the substrate in which the conductive structures may be formed is defined by a device isolation layer 105 in the field region of the substrate. A substrate 100 may be divided into the active region and the field region by a device isolation layer 105.

A gate insulation layer (not shown) may be formed on a semiconductor substrate 100 including a device isolation layer 105 by a thermal oxidation process or a chemical vapor deposition (CVD) process. The gate insulation layer may be only formed on the active region of the substrate that may be defined by a device isolation layer 105. A first conductive layer (not shown) and a gate mask 120 may be sequentially formed on the gate insulation layer. In one example embodiment of the present invention, the first conductive layer may include polysilicon doped with impurities and may be patterned into a gate electrode 115 during a subsequent process. In another example embodiment of the present invention, the first conductive layer may have a polycide structure that includes a doped polysilicon film, a metal silicide film and/or the like. A gate mask 120 may include a material having an etching selectivity to a first insulating interlayer (not shown) that may be formed on a semiconductor substrate 100 to a thickness to cover a gate structure 130 in a subsequent process. For example, when the first insulating interlayer includes an oxide, the gate mask 120 may include a nitride such as silicon nitride, silicon oxynitride and/or the like.

The first conductive layer and the gate insulation layer may be sequentially and partially etched off from the substrate 100 using a gate mask 120 as an etching mask to thereby form a gate electrode 115 and a gate insulation layer pattern 110 on a semiconductor substrate 100. As a result, a gate insulation layer pattern 110, a gate electrode 115 and a gate mask 120 may be sequentially stacked on a substrate 100, thereby forming a gate structure 130 on a substrate 100.

An insulation layer (not shown) may be formed on a semiconductor substrate 100 to a sufficient thickness to cover a gate structure 130. The insulation layer may be formed using a nitride such as silicon nitride, silicon oxynitride and/or the like. The insulation layer may be anisotropically etched off from a substrate 100 to thereby form a gate spacer 125 on a sidewall of a gate structure 130. As a result, a plurality of word lines may be formed on the active region of a semiconductor substrate 100 in parallel with one another. Each of the word lines may be electrically insulated from an adjacent word line by a gate spacer 125 on the sidewall of the word line and a gate mask 120 on a top surface of a gate structure 130.

Impurities may be implanted onto a surface of a semiconductor substrate 100 using a gate structure 130 as an implantation mask, and a heat treatment may be carried out on a substrate 100. A first and a second contract regions 135 and 140 may be formed on a substrate 100 as source/drain regions of a semiconductor device. In an example embodiment of the present invention, a first and a second contact regions 135 and 140 may correspond to a capacitor contact region and a bit line contact region, respectively.

FIG. 4 illustrates processing for forming a pad and a first insulating interlayer on a substrate.

Referring to FIG. 4, a first insulating interlayer 145 may be formed on a semiconductor substrate 100 to a sufficient thickness to cover a gate structure 130. A first insulating interlayer 145 may include an oxide and/or the like. For example, a first insulating interlayer 145 includes a boro-phosphor silicate glass (BPSG) layer, a phosphor silicate glass (PSG) layer, an undoped silicate glass (USG) layer, a spin on glass (SOG) layer, a tetraethylorthosilicate (TEOS) layer and/or the like formed through a plasma enhanced chemical vapor deposition (PECVD) process and an oxide layer and/or the like formed through a relatively high density plasma-chemical vapor deposition (HDP-CVD) process.

A first insulating interlayer 145 may be planarized until a top surface of a gate structure 130 may be exposed by a chemical mechanical polishing (CMP) process, an etchback process and/or a combination process of CMP and etch back. A top surface of a first insulating interlayer 145 becomes even and coplanar with a top surface of a gate mask 120. A first photoresist pattern (not shown) may be formed on a first insulating interlayer 145 and a first insulating interlayer 145 may be partially etched off from a substrate 100 by an anisotropic etching process using the first photoresist pattern as an etching mask to thereby form first contact holes (not shown) through which a first and second contact regions 135 and 140 may be exposed, respectively, through a first insulating interlayer 145.

When a first insulating interlayer 145 includes oxide and is partially etched off from a substrate 100, a gate mask 120 may have an etching selectivity with respect to a first insulating interlayer 145. Thus, a first contact holes 148 may be formed through a first insulating interlayer 145 in a self-alignment process with respect to a gate structure 130. A first contact region 135 corresponding to the capacitor contact region may be exposed through some of the first contact holes, and a second contact region 140 corresponding to the bit line contact region may be exposed through the rest of the first contact holes.

The first photoresist pattern may be removed from a first insulating interlayer 145 by an ashing process and/or a stripping process, and a second conductive layer (not shown) may be formed on the substrate including a first insulating interlayer 145 to a sufficient thickness to plug first contact holes 148. In an example embodiment of the present invention, the second conductive layer may include polysilicon heavily doped with impurities or a metal such as tungsten, aluminum, copper and/or the like.

The second conductive layer may be planarized by a planarization process until a top surface of a first insulating interlayer 145 may be exposed so that the second conductive layer remains in the first contact holes to thereby form first and second pads 150 and 155 on a substrate 100 through the self-alignment process. In an example embodiment of the present invention, a first pad 150 may be formed on a first contact region 135 corresponding to the capacitor contact region and a second pad 155 may be formed on a second contact region 140 corresponding to the bit line contact region. The planarization process may include a CMP process, an etchback process and a combination process of CMP and etch back process.

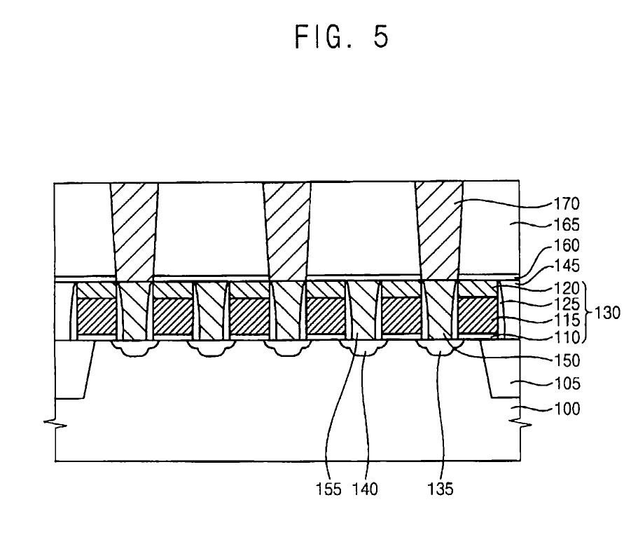

FIG. 5 illustrates processing for forming second and third insulating interlayers, and third and fourth pads on a substrate including the first insulating interlayer and the first and second contact pads.

Referring to FIG. 5, a second insulating interlayer 160 may be formed on first and second contact pads 150 and 155 and a first insulating interlayer 145. A bit line (not shown) may be electrically insulated from a first pad 150 by a second insulating interlayer 160. A second insulating interlayer 160 may include a BPSG layer, a PSG layer, an USG layer, a SOG layer, a TEOS layer and/or the like formed through a PECVD process and an oxide layer and/or the like formed through a HDP-CVD process.

A second photoresist pattern (not shown) may be formed on a second insulating interlayer 160, and a second insulating interlayer 160 may be partially etched off from a first insulating interlayer 145 and contact pads 150 and 155 using the second photoresist pattern as an etching mask to thereby form a second contact hole (not shown) through which a second pad 155 may be exposed. A third pad (not shown) may be formed in the second contact hole and the bit line may be electrically connected to a second contact pad 155 through the third pad.

The second photoresist pattern may be removed from a second insulating interlayer 160 including the second contact hole by an ashing process and/or a stripping process, and a third conductive layer (not shown) may be formed on a second insulating interlayer 160 to a sufficient thickness to plug the second contact hole. A top surface of the third conductive layer may be planarized through a planarization process. A bit line mask (not shown), which includes an etching mask for forming a bit line on a second insulating interlayer 160, may be then formed on the third conductive layer and the third conductive layer may be partially exposed through the bit line mask corresponding to the second contact hole through which a second pad 155 may be exposed.

The third conductive layer may be partially etched off from a second insulating interlayer 160 using the bit line mask as an etching mask, thereby forming a conductive pattern corresponding to the second contact hole. A portion of the conductive pattern plugging the second contact hole may function as a third pad, and the other portion of the conductive pattern that is formed on the third pad may function as a bit line electrode (not shown). The bit line mask may be formed on the bit line electrode. The third pad, the bit line electrode and the bit line mask may be formed into a bit line in a semiconductor device of an example embodiment of the present invention. The bit line may be electrically connected to a second pad 155 through the third pad. A nitride layer (not shown) may be formed on a second insulating interlayer 160 and the bit line may be anisotropically etched off from a second insulating interlayer 160 to thereby form a bit line spacer (not shown) on a sidewall of the bit line. The bit line spacer may sufficiently reduce damage to the bit line during a subsequent process to form a fourth pad 170.

A third insulating interlayer 165 may be formed on the second insulating interlayer 160 to a sufficient thickness to plug a space between the bit lines including the bit line spacer. A third insulating interlayer 165 may include a BPSG layer, a PSG layer, an USG layer, an SOG layer, a TEOS layer and/or the like formed through a PECVD process and an oxide layer and/or the like formed through a HDP-CVD process.

A third insulating interlayer 165 may be then planarized by a planarization process such as a CMP process and/or the like until a top surface of the bit line may be exposed so that the top surface of a third insulating interlayer 165 may become even and coplanar with the top surface of the bit line. A third photoresist pattern (not shown) may be formed on a third insulating interlayer 165 and third and second insulating interlayers 165 and 160 may be sequentially and anisotropically etched off from a substrate 100 using the third photoresist pattern as an etching mask, thereby forming a third contact hole (not shown) through which a first pad 150 may be exposed. In an example embodiment of the present invention, the third contact hole may be formed through a self-alignment process with respect to the bit line including the bit line spacer.

A fourth conductive layer (not shown) may be formed on a third insulating interlayer 165 to a sufficient thickness to plug the third contact hole. The fourth conductive layer may be planarized by a planarization process such as a CMP process and/or the like until top surfaces of a third insulating interlayer 165 and the bit line may be exposed so that the fourth conductive layer only remains in the third contact hole to thereby form a fourth pad 170 electrically connected to a first pad 150 on a second contact region 135. As an example embodiment of the present invention, a fourth pad 170 may include metal, polysilicon doped with impurities and/or the like. A lower electrode, which is to be formed in a subsequent process, may be electrically connected to a first pad 150 through a fourth pad 170.

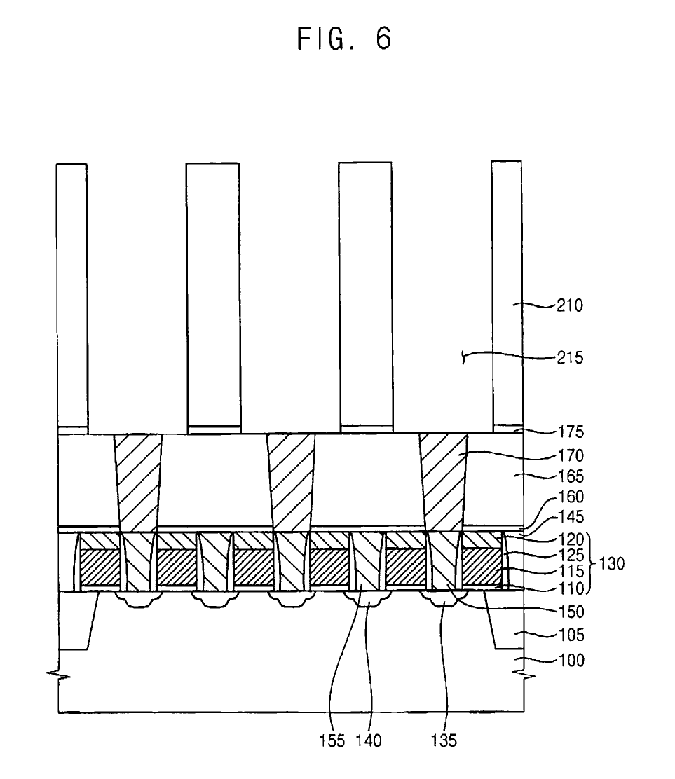

FIG. 6 illustrates processing for forming an etch stop layer and a mold layer having an opening 215 on the third insulating interlayer.

Referring to FIG. 6, an etch stop layer 175 may be formed on a fourth pad 170, a third insulating interlayer 165 and the bit line. An etch stop layer 175 may retard, or prevent, a fourth pad 170 from being etched off from a third insulating interlayer 165 during a subsequent etching process against the mold layer so as to form an opening 215. As an example embodiment of the present invention, an etch stop layer 175 may have a thickness of about 10 Å to about 300 Å. An etch stop layer 175 may include a material that may have an etching selectivity with respect to a mold layer 210. For example, an etch stop layer 175 may include a nitride layer and/or a metal nitride layer having a lower etching rate than a mold layer 210.

An oxide may be deposited on an etch stop layer 175 to form a mold layer. The mold layer may be formed using an oxide including BPSG, PSG, USG, SOG, PE-TEOS and/or the like.

A mold layer 210 may be formed on an etch stop layer 175 to a thickness of about 10,000 Å to about 20,000 Å. The thickness of a mold layer 210 may be varied in accordance with a desired capacitance of a capacitor of the semiconductor device. The capacitance of a capacitor may be decisively influenced by a height of the capacitor and the height of the capacitor may be determined by the thickness of a mold layer 210. Thus, the capacitance of a capacitor may be determined by varying the thickness of a mold layer 210.

A mask pattern (not shown) may be formed on a mold layer 210. The mask pattern may include a material having an etching selectivity with respect to a mold layer 210 such as an oxide and/or the like. A mold layer 210 may be partially and anisotropically etched off from an etch stop layer 175 using the mask pattern as an etching mask to thereby form an opening 215 through which an etch stop layer 175 may be partially exposed.

A portion of an etch stop layer 175 exposed through an opening 215 may be removed from a third insulating interlayer 165 and a fourth pad 170 so that a fourth contact pad 170 may be also exposed through an opening 215.

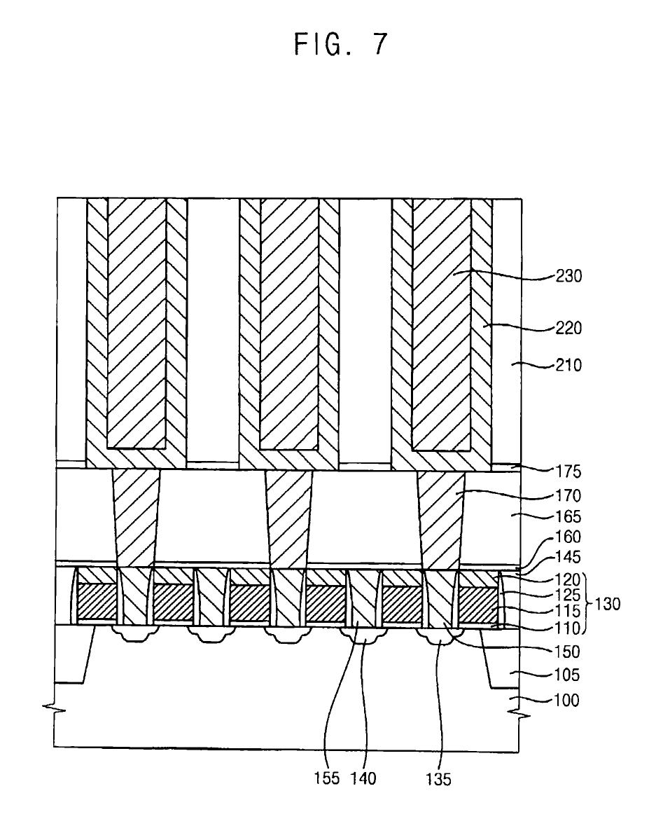

FIG. 7 illustrates processing for forming a lower electrode and a sacrificial photoresist pattern on a third insulating interlayer 165 and a fourth pad 170 exposed through an opening 215.

Referring to FIG. 7, a third conductive layer (not shown) may be formed on a sidewall and a bottom of an opening 215 and a mold layer 210 to a thickness of about 300 Å to about 500 Å by a deposition process. The third conductive layer may include doped polysilicon or a conductive material including a metal such as titanium nitride and/or the like. As a result, a size of an opening 215 may be reduced due to the third conductive layer along the sidewall and the bottom of an opening 215.

The sacrificial photoresist film (not shown) may be formed on the third conductive layer to a sufficient thickness to plug a reduced opening 215. A cleaning process may be performed on the substrate on which the resulting structure including the third conductive layer may be formed, and a photoresist composition may be coated on the third conductive layer, thereby forming a preliminary photoresist film on the substrate including the third conductive layer. A first baking process may be performed on the preliminary photoresist film so as to improve an adhesive strength of the preliminary photoresist film with respect to the third conductive layer. An exposing process and a second baking process may be sequentially carried out on the preliminary photoresist film, thereby finally forming the sacrificial photoresist film on the third conductive layer.

An opening 215 may have an aspect ratio of about 1:9 to about 1:40, for example, an aspect ratio of about 1:15 to about 1:30.

The third conductive layer and the sacrificial photoresist film may be planarized by a planarization process until a top surface of a mold layer 210 may be exposed so that the third conductive layer and the sacrificial photoresist film only remain in an opening 215, thereby to form a lower electrode 220 and a sacrificial pattern 230 in an opening 215. The planarization process may include a CMP process, an etchback process and/or a combination process of the CMP and etch back processes.

A sacrificial pattern 230 may be formed in an opening 215 simultaneously with a lower electrode 220 in a node separation process as described above. A sacrificial pattern 230 may retard, or prevent, damage to a lower electrode 220 during the node separation process and a subsequent etching process against a mold layer 210. A mold layer 210 may be etched off from an etch stop layer 175 and a sacrificial pattern 230 plugging an opening 215, and may be removed from a lower electrode 220 so that lower electrode 220 remains on a third insulating interlayer 165 and makes contact with a fourth pad 170. In such a case, the opening in a lower electrode 220 and a sacrificial pattern 230 may have such a relatively high aspect ratio that it may be difficult to remove a sacrificial pattern 230 from the substrate including a lower electrode 220 with an ashing process using oxygen plasma or ozone plasma.

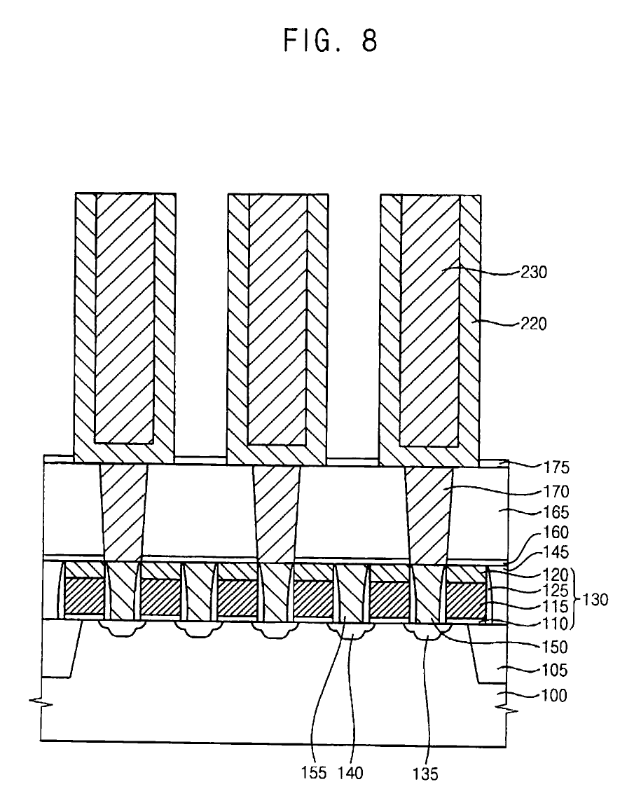

Referring to FIG. 8, a mold layer 210 may be removed from an etch stop layer 175, so that an outer wall of a lower electrode 220 may be exposed. Most of a sacrificial pattern 230 may still remain in an opening 215 due to an etching selectivity with respect to a mold layer 210. A sacrificial pattern 230 may not be removed from a lower electrode 220 during the etching process.

The etching process for removing a mold layer 210 may use an etching solution or an etching gas of which an etching rate against a lower electrode 220 may be lower than against a mold layer 210.

In one example embodiment of the present invention, a wet etching process may be performed on the substrate for removing a mold layer 210 from an etch stop layer 175, and a limulus amebocyte lysate (LAL) solution that is a mixture of ammonium fluoride (NH₄F), hydrogen fluoride (HF) and deionized water and/or the like may be used as an etchant for the wet etching process. In another example embodiment of the present invention, a dry etching process may be performed on the substrate for removing a mold layer 210 from an etch stop layer 175, and a mixture gas including hydrogen fluoride (HF), isopropyl alcohol (IPA) and/or deionized water may be used as an etching gas for the dry etching process.

A cleaning process may be carried out after removing a mold layer 210 so that a residual etching solution/gas and particles remaining on a sacrificial pattern 230 and a lower electrode 220 may be sufficiently removed from a sacrificial pattern 230 and a lower electrode 220. For example, the cleaning process may use IPA and/or deionized water as a cleaning solution for the cleaning process.

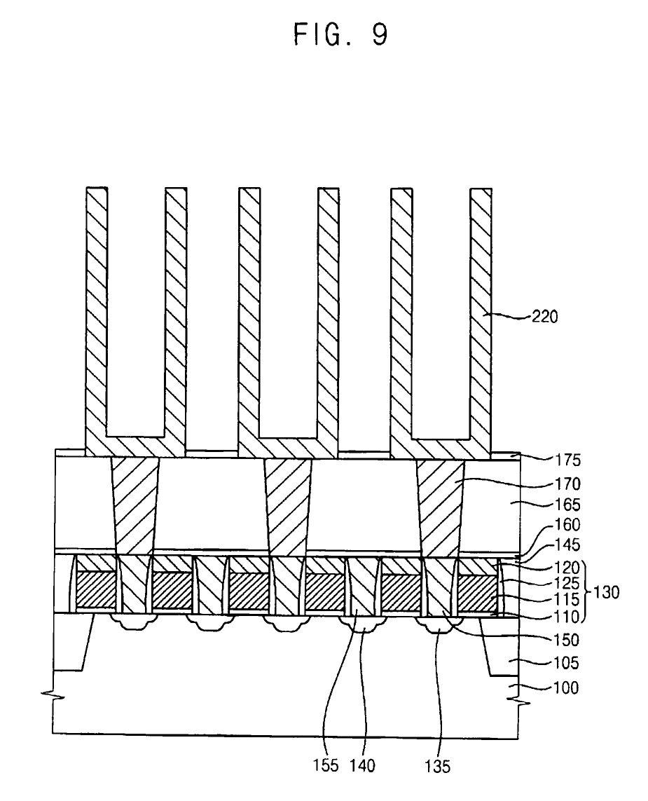

FIG. 9 illustrates a process for removing the sacrificial pattern from the lower electrode.

Referring to FIG. 9, a sacrificial pattern 230 may be removed from a lower electrode 220 so that no residual sacrificial pattern 230 remains on the lower electrode 220, and the lower electrode 220 may be formed on a third insulating interlayer 165 as a cylindrical structure.

In an example embodiment of the present invention, an oxidation decomposition process using ozone gas and a rinsing process may be sequentially performed on the substrate including a lower electrode 220 and a sacrificial pattern 230, thereby to remove a sacrificial pattern 230 from a lower electrode 220.

For example, the ozone gas having a relatively high pressure may be provided onto a substrate 100 including a sacrificial pattern 230, and a sacrificial pattern 230 may be decomposed through an oxidation reaction using the ozone gas. The ozone gas may be generated by an ozone generator using an oxygen gas. The ozone gas may have a gas density of about 150 g/m³ to about 250 g/m³. Further, the oxidation decomposition process may be performed at a temperature of about 80° C. to about 120° C. under a pressure of about 40 kpa to about 100 kpa.

The oxidation decomposition process for a sacrificial pattern 230 may be initiated by a chemical reaction between ozone (O₃) and/or carbon (C) in the polymer of a sacrificial pattern 230. In particular, ozone (O₃) and/or oxygen (O₂) in the ozone gas may be reacted with carbon (C) in the polymer of a sacrificial pattern 230 to generate carbon dioxide (CO₂) and/or carbon oxide (CO). Because a decomposed sacrificial pattern 230 may have a characteristic of relatively high solubility with respect to water, a subsequent rinsing process may easily remove a sacrificial pattern 230 from a lower electrode 220.

In an example embodiment of the present invention, an ashing process using oxygen plasma, an oxidation decomposition process using ozone gas and a rinsing process may be sequentially performed on the substrate including a sacrificial pattern 230 and a lower electrode 220 to thereby remove a sacrificial photoresist pattern 230 from a lower electrode 220.

For example, an oxygen gas and an inactive gas may be provided into a plasma reaction chamber and may be excited into plasma, a sacrificial pattern 230 may be partially removed from a lower electrode 220 using the oxygen plasma. A photoresist pattern functioning as an etching mask for an etching process may be sufficiently removed from a substrate by the above ashing process using the oxygen plasma.

Ozone gas may be provided onto a substrate 100 having a residual sacrificial pattern 230 at a gas density of about 150 g/m³ to about 250 g/m³, and the residual sacrificial pattern may be decomposed by an oxidation reaction using the ozone gas. A residual sacrificial pattern 230 may be sufficiently removed from a lower electrode 220. For example, a residual sacrificial pattern 230 may be decomposed at a temperature of about 80° C. to about 120° C. under a pressure of about 40 kpa to 100 kpa.

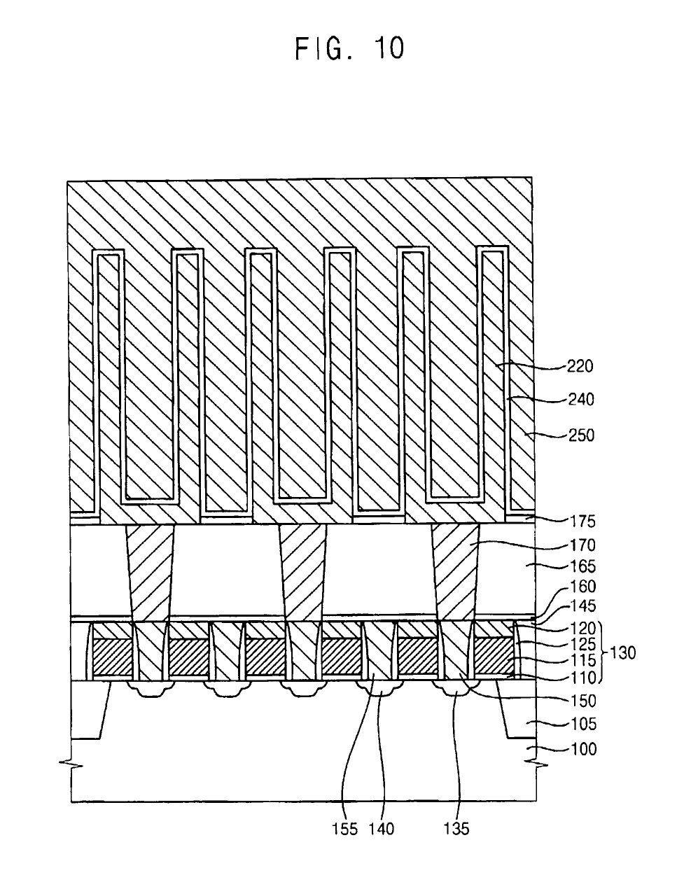

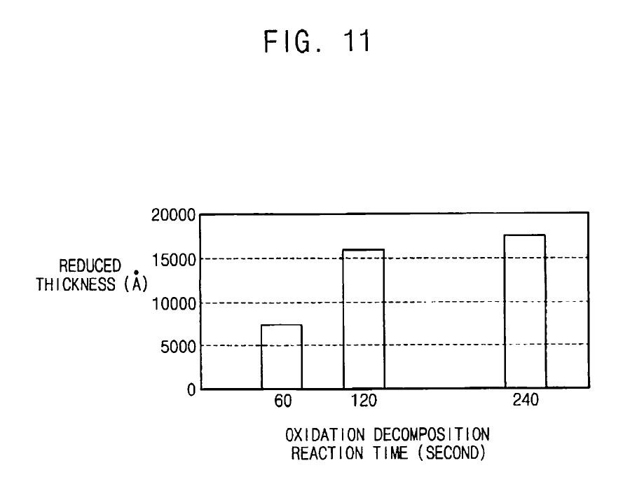

FIG. 10 illustrates processing for forming a dielectric layer and an upper electrode on the lower electrode.

Referring to FIG. 10, a dielectric layer 240 including a metal oxide and/or the like may be formed on a lower electrode 220 by a deposition process such as an atomic layer deposition (ALD) process and/or a CVD process. When the ALD process is performed to form a dielectric layer 240, a dielectric layer 240 may include an aluminum oxide layer and/or a hafnium oxide layer.

An upper electrode 250 may be formed on a dielectric layer 240. The upper electrode may include a conductive material such as polysilicon, metal and/or metal nitride like a lower electrode 220. An upper electrode 250 may also be formed through a CVD process and/or the like.

As a result, a lower electrode 220, a dielectric layer 240 and an upper electrode 250 may be stacked on a third insulating interlayer 165 to thereby complete a capacitor on a substrate 100.

Evaluation for a Photoresist Film Removal Ability

A photoresist film removal ability was estimated on the condition that ozone gas was provided into a processing chamber in accordance with an example embodiment of the present invention. A photoresist film was formed on a substrate to a thickness of about 2000 Å using an AZ9260 (a trademark of a novolak resin manufactured by CLARIENT Co. in Japan) as a working specimen for evaluating the photoresist film removal ability.

The working specimen was positioned on a plate in a processing chamber, and the ozone gas was provided onto the working specimen at a gas density of about 150 g/m³ to about 250 g/m³. The photoresist film was removed from the working specimen through an oxidation-decomposition reaction using the ozone gas for a reaction time of about 60 seconds, about 120 seconds and about 240 seconds, respectively. Thereafter, a cleaning process was carried out on the working specimen including the decomposed photoresist film through a rinsing process using deionized water. A removal state of the photoresist film was measured as shown in FIG. 11.

FIG. 11 is a graph showing a removal amount of the photoresist film in relation to a reaction time of the oxidation-decomposition reaction.

Referring to FIG. 11, when the oxidation-decomposition reaction to the photoresist film was maintained for about 60 seconds using the ozone gas, the amount of the photoresist film thickness was decreased up to about 7,500 Å. When the oxidation-decomposition reaction to the photoresist film was maintained for about 120 seconds, the amount of the photoresist film thickness was decreased up to about 16,000 Å. However, when the oxidation-decomposition reaction was maintained for about 240 seconds, the amount of the photoresist film thickness was only decreased about 17,500 Å.

The above experimental results show that about 87.5% of the photoresist film was removed from the working specimen for about the first 240 seconds and a removal rate of the photoresist film was stagnated after about 120 seconds after the reaction begins. Consequently, when the oxidation-decomposition reaction is maintained for at least about 120 seconds on the condition that an ashing process is additionally performed so as to remove at least about 20% of the photoresist film, the photoresist film having the thickness of about 20,000 Å may be sufficiently removed from the working specimen by both the ashing process and the oxidation-decomposition process due to the ozone gas. As a result, the ashing process and the oxidation-decomposition process using the ozone gas may sufficiently remove the photoresist film having a thickness of more than about 16,000 Å despite the higher aspect ratio of the photoresist film. For example, when a photoresist film is formed on a substrate to a thickness of about 16,000 Å, the above experimental results indicate that the oxidation-decomposition process using ozone gas may sufficiently remove a photoresist film from a substrate without an additional ashing process. And when a photoresist film is formed on a substrate to a thickness of more than about 16,000 Å, the ashing process and the oxidation-decomposition process may sufficiently remove the photoresist film from the substrate, thereby improving a throughput of the semiconductor device.

According to example embodiments of the present invention, a photoresist pattern that remains in an opening having a relatively high aspect ratio may be sufficiently removed from a substrate by a cleaning process using ozone gas. Thus, no residual photoresist pattern remains on the substrate in the opening to reduce resistance of a capacitor.

Further, the photoresist pattern in the opening of a relatively high aspect ratio may be sufficiently removed from the substrate without increasing process time and process temperature, thereby to improve a throughput of manufacturing a semiconductor device.

The foregoing is illustrative of example embodiments of the present invention and is not to be construed as limiting thereof. Although a few example embodiments of the present invention have been described, those skilled in the art will readily appreciate that many modifications may be possible in the example embodiments of the present invention without materially departing from the novel teachings and advantages of the present invention. Accordingly, all such modifications are intended to be included within the scope of example embodiments of the present invention as defined in the claims. In the claims, means-plus-function clauses are intended to cover the structures described herein as performing the recited function and not only structural equivalents but also equivalent structures. Therefore, it is to be understood that the foregoing is illustrative of example embodiments of the present invention and is not to be construed as limited to the specific embodiments disclosed, and that modifications to the disclosed embodiments, as well as other example embodiments, are intended to be included within the scope of the appended claims. Example embodiments of the present invention are defined by the following claims, with equivalents of the claims to be included therein.

What is claimed is:

1. A method of removing a photoresist pattern, comprising:
providing ozone gas onto a substrate on which the photoresist pattern is formed; and
performing an oxidation-decomposition process using the ozone gas on the substrate including the photoresist pattern, thereby to remove the photoresist pattern from the substrate.

2. The method of claim 1, further comprising:
performing an ashing process using plasma to partially remove the photoresist pattern from the substrate.

3. The method of claim 1, further comprising:
performing a rinsing process using water so that the decomposed photoresist pattern due to the oxidation-decomposition process is dissolved into the water.

4. The method of claim 1, wherein the ozone gas has a gas density of about 150 g/m³ to about 250 g/m³.

5. The method of claim 1, wherein the oxidation-decomposition process is carried out at a temperature of about 80° C. to about 120° C.

6. The method of claim 1, wherein the oxidation-decomposition process is carried out under a pressure of about 40 kpa to about 100 kpa.

7. The method of claim 1, wherein the substrate includes an opening in which the photoresist pattern is formed.

8. The method of claim 7, wherein the opening has an aspect ratio of about 1:9 to about 1:40.

9. The method of claim 8, wherein the opening has an aspect ratio of about 1:15 to about 1:30.

10. The method of claim 7, further comprising:
continuously forming a conductive pattern on a sidewall and a bottom of the opening.

11. A method of manufacturing a semiconductor device, comprising:
forming a mold layer having an opening on a substrate;
continuously forming a lower electrode layer on a sidewall and a bottom of the opening and on the mold layer;
forming a photoresist film on the mold layer to a thickness to plug the opening;
planarizing the photoresist film and the lower electrode layer by a planarization process until a top surface of the mold layer is exposed so that the lower electrode layer and the photoresist film remain only in the opening, thereby to form a lower electrode and a photoresist pattern on the substrate; and
removing the photoresist pattern from the substrate according to claim 1.

12. The method of claim 11, further comprising:
partially removing the photoresist pattern from the substrate by an ashing process using oxygen plasma.

13. The method of claim 11, further comprising:
removing the mold layer from the substrate to expose the lower electrode.
